(19) United States
(12) Patent Application Publication
(10) Pub. No.: US 2026/0242571 A1
(43) Pub. Date: Aug. 20, 2026

(54) NANORATTLE FILLERS AND METHODS OF USE THEREOF

(71) Applicant: ARIZONA BOARD OF REGENTS ON BEHALF OF ARIZONA STATE UNIVERSITY, Scottsdale, AZ (US)

(72) Inventor: Yoan Simon, Phoenix, AZ (US)

(21) Appl. No.: 19/541,181

(22) Filed: Feb. 16, 2026

Related U.S. Application Data
(60) Provisional application No. 63/758,702, filed on Feb. 14, 2025.

(51) Int. Cl. C08K 9/02; C08J 3/20; H10W 74/47

(52) U.S. Cl. CPC C08K 9/02; C08J 3/20; H10W 74/473; C08K 2201/003; C08K 2201/011; H10W 74/476

(57) ABSTRACT

The disclosure encompasses nanorattle fillers, core-shell fillers, polymer resins and polymer materials comprising nanorattle fillers or core-shell fillers, and methods of making and using the same. In embodiments, the compositions and methods described herein can be used in manufacturing, for example, in the semiconductor industry.

This application claims priority to U.S. Provisional Application No. 63/758,702 filed on Feb. 14, 2025, the entire contents of which are incorporated herein by reference.

All patents, patent applications and publications cited herein are hereby incorporated by reference in their entirety. The disclosures of these publications in their entireties are hereby incorporated by reference into this application in order to more fully describe the state of the art as known to those skilled therein as of the date of the invention described and claimed herein.

This patent disclosure contains material that is subject to copyright protection. The copyright owner has no objection to the facsimile reproduction by anyone of the patent document or the patent disclosure as it appears in the U.S. Patent and Trademark Office patent file or records but otherwise reserves any and all copyright rights.

### FIELD OF THE INVENTION

The present invention relates to core-shell fillers, nanorattle fillers, polymer resins and polymer materials comprising said fillers and methods of making and using the same.

### BACKGROUND OF THE INVENTION

There is a growing need for the development of materials-based strategies that will enable remote and local heating of the resin to induce curing without having to heat up the entire assembly.

### SUMMARY OF THE INVENTION

Aspects of the disclosure are drawn towards a composite resin composition comprising a polymer resin and a nanoparticle filler, wherein the nanoparticle filler comprises: a nanoparticle core, wherein the core comprises a material that is remotely heatable by exposure to an oscillating field; an insulative coating surrounding the core; at least one porous external insulative shell; and a void disposed between the insulative coating and the at least one porous external insulative shell. In some embodiments, the polymer resin is not photocurable. In embodiments, the material is selected from the group consisting of a metal, a metal oxide, a metal alloy, a carbonaceous material, a metal nitride, a metal carbide, or a composite material thereof. In embodiments, the insulative coating comprises silica. In embodiments, the at least one porous external insulative shell comprises a material selected from the group consisting of a glassy polymer, mesoporous silica, nanoporous silica, or a combination thereof. In some embodiments, the nanoparticle filler does not comprise a ceramic. In embodiments, the nanoparticle core has a diameter of about 5 nm to about 25 nm. In embodiments, the insulative shell coating has a thickness of about 10 nm to about 50 nm. In embodiments, the at least one porous external insulative shell has a thickness of about 5 nm to about 30 nm. In embodiments, the void comprises about 5 nm to about 50 nm. In embodiments, the nanoparticle core is selected from an iron oxide nanoparticle, a cobalt nanoparticle, a gold nanoparticle, a titanium dioxide nanoparticle, a silicon dioxide nanoparticle, a zinc oxide nanoparticle, or an aluminum oxide nanoparticle. In embodiments, the iron oxide nanoparticle is a magnetite iron oxide nanoparticle. In embodiments, the composition comprises about 0.1 wt. % to about 20 wt. % of the nanoparticle filler. In embodiments, the composition is a capillary underfill, a molded underfill, an over-mold material, or an encapsulant. In embodiments, the polymer resin is a thermosetting resin. In embodiments, the thermosetting resin is selected from the group consisting of an epoxy resin, a phenol resin, a polyimide, an acrylate resin, a silicone resin, or a combination thereof. In embodiments, the polymer resin is a thermoplastic resin. In embodiments, the thermosetting resin is selected from the group consisting of a polyethylene, a polypropylene, a polyvinyl chloride, a polystyrene, a polyethylene terephthalate, a polyurethane, an ethyl vinyl acetate, or a combination thereof.

Aspects of the disclosure are drawn towards a method of producing a molding composition. In embodiments, the method comprises loading a nanoparticle filler into a polymer resin, thereby producing a composite resin. In embodiments, the nanoparticle filler comprises a nanoparticle core, wherein the core comprises a material that is remotely heatable by exposure to an oscillating field; an insulative coating surrounding the core, at least one porous external insulative shell, and a void between the insulative shell coating and the at least one porous external insulative shell. In embodiments, the method comprises depositing the composite resin onto a substrate or into a mold; and exposing the composite resin to an oscillating field, thereby curing the composite resin and forming a molding composition. In embodiments, the oscillating field is an oscillating magnetic field. In embodiments, the oscillating magnetic field has a frequency of about 20 kHz to about 1.0 MHz. In embodiments, the composite resin is exposed to the oscillating field for about 10 seconds to about 5 minutes. In embodiments, the nanoparticle core comprises a material selected from the group consisting of a metal, a metal oxide, a metal alloy, carbon material, a metal nitride, a metal carbide, or a combination thereof. In embodiments, the insulative shell coating comprises dense silica. In embodiments, the at least one porous external insulative shell comprises a material selected from the group consisting of a glassy polymer, mesoporous silica, nanoporous silica, or a combination thereof. In embodiments, the nanoparticle filler does not comprise a ceramic. In embodiments, the nanoparticle filler is loaded at about 0.1 wt. % to about 20 wt. % of the composite resin. In embodiments, the nanoparticle core has a diameter of about 5 nm to about 25 nm. In embodiments, the insulative shell coating has a thickness of about 10 nm to about 50 nm. In embodiments, the at least one porous external insulative shell has a thickness of about 5 nm to about 30 nm. In embodiments, the void comprises about 5 nm to about 50 nm. In embodiments, the core is selected from an iron oxide nanoparticle, a cobalt nanoparticle, or a gold particle. In embodiments, the void disposed between the insulative shell coating and the at least one porous external insulative shell is produced by subjecting the nanoparticle core to magnetization roasting. In embodiments, the void disposed between the insulative shell coating and the at least one porous external insulative shell is produced by coating the nanoparticle core with an insulative coating; encapsulating the insulative shell coating with an external silica-organic insulative outer shell; and subjecting the nanoparticle filler to hydrothermal treatment, thereby producing a void. In embodiments, the molding composition is a capillary underfill, a molded underfill, an over-mold material, or an encapsulant. In embodiments, the polymer resin comprises a thermosetting resin or a thermoplastic resin. In embodiments, the thermosetting resin selected from the group consisting of an epoxy resin, a phenol resin, a polyimide, an acrylate resin, a silicone resin, or a combination thereof. In embodiments, the thermoplastic resin selected from the group consisting of a polyethylene, a polypropylene, a polyvinyl chloride, a polystyrene, a polyethylene terephthalate, a polyurethane, an ethyl vinyl acetate, or a combination thereof.

Aspects of the disclosure are drawn towards a multidie assembly comprising a molding composition produced by the method described herein. In embodiments, the molding composition is a capillary underfill, a molded underfill, an over-mold material, or an encapsulant.

Other objects and advantages of this invention will become readily apparent from the ensuing description.

### BRIEF DESCRIPTION OF THE FIGURES

FIG. 1 shows a non-limiting, exemplary schematic representation of the ring-opening metathesis polymerization of norbornene in the presence of 5-norbornene-2-carboxylic acid functionalized Fe₃O₄ nanoparticles, leading to polymer networks in which the Fe₃O₄ nanoparticles serve as multifunctional cross-linkers.

FIG. 2 shows non-limiting, exemplary pictures showing the unfolding of the strip with 1 wt. % NPs upon application of a 1.8 MHz oscillating magnetic field at t=0, 12, 16, and 30 s.

FIG. 3 shows a non-limiting, exemplary illustration of showing varying silica shell thickness in core-shell nanofiller under an embodiment.

FIG. 4 shows a non-limiting, exemplary illustration of a process for creating a core-coating-void-shell (i.e., nanorattle) nanofiller under an embodiment. The process can comprise coating a hematite core with a dense silica layer, forming an organic-silica layer (e.g., by sol-gel polymerization of TEOS and C18TMS), generating a void by subjecting the filler to hydrothermal conditions, subjecting the nanofiller to calcination to remove the organic groups from the organic-silica layer to generate porosity in the outer shell, and reducing the hematite core (e.g., through H2 reduction) to produce a magnetite core (adapted from W. Zhao, J. Gu, L. Zhang, H. Chen, J. Shi, J. Am. Chem. Soc. 2005,127, 8916).

### DETAILED DESCRIPTION OF THE INVENTION

Detailed descriptions of one or more embodiments are provided herein. It is to be understood, however, that the invention can be embodied in various forms. Therefore, specific details disclosed herein are not to be interpreted as limiting, but rather as a basis for the claims and as a representative basis for teaching one skilled in the art to employ the invention in any appropriate manner.

The singular forms “a”, “an” and “the” include plural reference unless the context clearly dictates otherwise. The use of the word “a” or “an” when used in conjunction with the term “comprising” in the claims and/or the specification can mean “one,” but it is also consistent with the meaning of “one or more,” “at least one,” and “one or more than one.”

Wherever any of the phrases “for example,” “such as,” “including” and the like are used herein, the phrase “and without limitation” is understood to follow unless explicitly stated otherwise. Similarly, “an example,” “exemplary” and the like are understood to be nonlimiting.

The term “substantially” allows for deviations from the descriptor that do not negatively impact the intended purpose. Descriptive terms are understood to be modified by the term “substantially” even if the word “substantially” is not explicitly recited.

The terms “comprising” and “including” and “having” and “involving” (and similarly “comprises”, “includes,” “has,” and “involves”) and the like are used interchangeably and have the same meaning. Specifically, each of the terms is defined consistent with the common United States patent law definition of “comprising” and is therefore interpreted to be an open term meaning “at least the following,” and is also interpreted not to exclude additional features, limitations, aspects, etc. Thus, for example, “a process involving steps a, b, and c” means that the process includes at least steps a, b and c. Wherever the terms “a” or “an” are used, “one or more” is understood, unless such interpretation is nonsensical in context.

As used herein, the term “about” can refer to approximately, roughly, around, or in the region of. When the term “about” is used in conjunction with a numerical range, it modifies that range by extending the boundaries above and below the numerical values set forth. In general, the term “about” is used herein to modify a numerical value above and below the stated value by a variance of 20 percent up or down (higher or lower). In embodiments, the term “about” can be denoted by “~”.

As used herein, the term “substantially the same” or “substantially” can refer to variability typical for a particular method is taken into account.

The terms “sufficient” and “effective”, as used interchangeably herein, can refer to an amount (e.g., mass, volume, dosage, concentration, and/or time period) needed to achieve one or more desired result(s).

Before explaining at least one embodiment of the disclosure in detail, it is to be understood that the disclosure is not necessarily limited in its application to the details set forth in the following description or exemplified by the examples. The disclosure can be used for other embodiments or of being practiced or carried out in various ways. Other compositions, compounds, methods, features, and advantages of the disclosure will be or become apparent to one having ordinary skill in the art upon examination of the following drawings, detailed description, and examples. All such additional compositions, compounds, methods, features, and advantages can be included within this description, and be within the scope of the disclosure.

As such, aspects of the disclosure are drawn towards composite resin composition comprising a polymer resin and a nanoparticle filler. As used herein the terms “nanoparticle filler” and “nanofiller” can be used interchangeably. In embodiments, the nanoparticle filler comprises a nanoparticle core that is remotely heatable upon exposure to an oscillating field.

Oscillating fields can include but are not limited to low frequency magnetic fields, radio waves, microwaves, and the like. In exemplary embodiments the oscillating field can be a low frequency magnetic field. In some embodiments, the oscillating field can be high frequency radio waves. In exemplary embodiments, a low frequency magnetic field can induce heating in the nanoparticle core.

In some embodiments, the nanoparticle filler can comprise an insulative coating surrounding the core. The insulative coating modulates the amount of energy transferred from the conductive nanoparticle core to its surrounding environment resulting from exposing the conductive nanoparticle core to an oscillating field. For example, a thicker insulative coating can lower the amount of energy transferred to the surroundings and a thinner core can increase the amount of energy transferred to the surroundings. In exemplary embodiments, a remotely heatable nanoparticle core with an insulative coating can be heated using a low frequency magnetic field and the amount of heat transferred to the surroundings can be modulated by the thickness of the insulative coating.

In some embodiments, the insulative coating can comprise a thickness of about 10 nm to about 50 nm. In exemplary embodiments, the insulative coating can have a thickness of about 25 nm to about 30 nm. In some embodiments, the insulative coating can have a thickness of about 10 nm to about 25 nm. In some non-limiting, exemplary embodiments, the insulative core can comprise a thickness of about 10 nm, about 15 nm, about 20 nm, about 25 nm, about 30 nm, about 35 nm, about 40 nm, about 45 nm, or about 50 nm. In some embodiments, the insulative coating surrounding the core can comprise multiple insulative coating layers deposited on the surface of the nanoparticle core. In exemplary embodiments, the insulative shell coating can comprise silica or a composite thereof. In some exemplary embodiments the insulative shell coating can be a dense silica insulative shell coating.

In embodiments, the nanoparticle filler can comprise at least one porous external insulative shell. In some embodiments, the nanoparticle filler can comprise a plurality of porous external shells. In exemplary embodiments the at least one external insulative shell is deposited on top of the insulative coating that surrounds the conductive nanoparticle core.

In embodiments, there can be a second porous external shell deposited on top of the insulating external porous shell. In some embodiments, the external shell does not contain pores.

In exemplary embodiments, the porous insulative shell can comprise a glassy polymer external insulative shell, mesoporous silica external insulative shell, a nanoporous silica external insulative shell, or a combination thereof. In some exemplary embodiments, the nanoparticle filler can comprise at least one nanoporous silica external insulative shell and at least one mesoporous silica external insulative shell. In some exemplary embodiments, the nanoparticle filler does not comprise a porous external insulative shell.

In embodiments, the silica described herein can be passivated or surface treated by methods known in the art. For example, the silica can be subjected to thermodehydroxylation at high temperatures to remove hydroxyl groups. In some embodiments, the silica can be reacted with silanes depending on the surface characteristics which can be determined by one of ordinary skill in the art. In some embodiments, the silanols on the silica can be reacted with siloxane groups to increase compatibility with the polymer resin matrix. In embodiments, the siloxanes can be functional (e.g., containing amine groups like (3-aminopropyl)triethoxysilane) or passivating (e.g., alkyl trialkoxysilanes).

In some embodiments, the at least one external insulative shell can have a thickness of about 5 nm to about 30 nm. In some embodiments, the at least one external shell can comprise about 10 nm to about 20 nm. For example, in some exemplary embodiments, the nanoparticle of an embodiment described herein can comprise a thickness of about 5 nm, about 7 nm, about 10 nm, about 12 nm, about 14 nm, about 16 nm, about 18 nm, about 20 nm, about 22 nm, about 24 nm, about 26 nm, about 28 nm, about 30 nm, about 32 nm, about 34 nm, or about 35 nm.

In some embodiments, the nanocomposite filler can comprise a void space. In exemplary embodiments, the void space is disposed between the insulative coating and the at least one porous external insulative shell. In further embodiments, the void space can be disposed between the at least one porous external insulative shell and a second porous external insulative shell. In some embodiments, the void space can be disposed between the conductive nanoparticle core and the at least one porous external insulative shell where the conductive nanoparticle core does not comprise an insulative coating.

In some embodiments the nanoparticle filler comprises a magnetic nanoparticle core, an insulative coating surrounding the core, and no porous external insulative shell or void space. The presence of a void space of any of the embodiments described herein can allow for movement of the nanoparticle core within the at least one porous silica external insulative shell.

Embodiments of the disclosure described herein comprise a remotely heatable nanoparticle core. In some embodiments, the remotely heatable nanoparticle core is a magnetic nanoparticle core. In embodiments, the remotely heatable nanoparticle core can be selected from a metal core, a metal oxide core, a metal alloy core, a carbon material core, a conductive polymer core, an MXene core, a metal nitride core, a metal carbide core, a silicon core, or a composite material core thereof.

In exemplary embodiments, the nanoparticle core can be a metal oxide nanoparticle core. In some exemplary embodiments, that metal oxide nanoparticle core can be an iron oxide nanoparticle core. In some embodiments, the nanoparticle core can be selected from an iron oxide nanoparticle, a cobalt nanoparticle, a gold nanoparticle, a titanium dioxide nanoparticle, a silicon dioxide nanoparticle, a silicon dioxide nanoparticle, a zinc oxide nanoparticle, or an aluminum oxide nanoparticle. In some exemplary embodiments the iron oxide nanoparticle can be a magnetite iron oxide nanoparticle or a hematite iron oxide nanoparticle. In an embodiment the conductive nanoparticle core can be a hematite iron oxide nanoparticle. In an embodiment the nanoparticle core can be a magnetite iron oxide nanoparticle core.

In some embodiments, the nanoparticle core can have a diameter of about 5 nm to about 25 nm. For example, in some exemplary embodiments the nanoparticle core can have a diameter of about 4nm, about 5 nm, about 6 nm, about 7 nm, about 8 nm, about 9 nm, about 10 nm, about 11 nm, about 12 nm, about 13 nm, about 14 nm, about 15 nm, about 16 nm, about 17 nm, about 18 nm, about 19 nm, about 20 nm, about 21 nm, about 22 nm, about 23 nm, about 24 nm, about 25 nm, or about 26 nm.

As used herein, diameter can refer to the hydrodynamic diameter of a nanoparticle as measured using Dynamic Light Scattering (DLS) techniques, or diameter can refer to precise physical dimensions and morphology as measured by Scanning Electron Microscopy (SEM) or Transmission Electron Microscopy (TEM). Those techniques used to measure diameter of the nanoparticle core are known the art.

In some embodiments, the nanoparticle filler does not comprise a ceramic.

In an embodiment of the composition described herein the composite resin can comprise a nanoparticle filler loading of about 0.1 wt. % to about 20 wt. %. For example, the composite resin of an embodiment can comprise a nanoparticle filler loading of about 0.1 wt. %, about 0.5 wt. %, about 1.0 wt. %, about 1.5 wt. %, about 2.0 wt. %, about 2.5 wt. %, about 3.0 wt. %, about 3.5 wt. %, about 4.0 wt. %, about 4.5 wt. %, about 5.0 wt. %, about 5.5 wt. %, about 6.0 wt. %, about 6.5 wt. %, about 7.0 wt. %, about 7.5 wt. %, about 8.0 wt. %, about 8.5 wt. %, about 9.0 wt. %, about 9.5 wt. %, about 10.0 wt. %, about 10.5 wt. %, about 11.0 wt. %, about 11.5 wt. %, about 12.0 wt. %, about 12.5 wt. %, about 13.0 wt. %, about 13.5 wt. %, about 14.0 wt. %, about 14.5 wt. %, about 15.0 wt. %, about 15.5 wt. %, about 16.0 wt. %, about 16.5 wt. %, about 17.0 wt. %, about 17.5 wt. %, about 18.0 wt. %, about 18.5 wt. %, about 19.0 wt. %, about 19.5 wt. %, or about 20.0 wt. %.

In some embodiments, the composition of any embodiment described herein can be a capillary underfill, a molded underfill, and over-molder material, or an encapsulant. As described herein, a capillary underfill can refer to a material used in chip manufacturing or fabrication that can flow via capillary action into gaps between components. Once gaps are filled the material can be cured securing said components in place. An over-mold material as described herein can refer to a material used in injection molding techniques well known in the art, that serves the purpose of applying a secondary layer of material over a substrate creating a packaging material. A molded underfill as described herein can refer to a material used in chip manufacturing or fabrication that can serve the dual purpose of securing components to their substrates and serving as an over-mold material. Embodiments described herein can serve as a molded underfill material and offer the advantage of aiding both in a curing and/or a healing process.

The polymer resin described herein can be any thermosetting resin known in the art or any thermoplastic resin known in the art. In exemplary embodiments, the thermosetting resin can be an epoxy resin, a phenolic resin, a polyimide resin, an acrylate resin, a silicone resin, or combinations thereof. In some exemplary embodiments, the thermoplastic resin can be a polyethylene resin, a polypropylene resin, a polyvinyl chloride resin, a polystyrene resin, a polyethylene terephthalate resin, a polyurethane resin, an ethyl vinyl acetate resin, or combinations thereof. In some embodiments, the polymer resin can be a polymer resin that is not photocurable. However, the resin can be cured through the heat generated from the nanoparticle being exposed to the oscillating field.

Further aspects of the disclosure are drawn toward a method of producing a molding composition. Methods described herein can comprise loading a nanoparticle filler into a polymer resin thereby producing a composite resin. The composite resin described herein can be deposited onto a substrate or into a mold and exposed to an oscillating magnetic field thereby curing the composite resin and forming a molding composition. In some embodiments, the nanoparticle filler can comprise a conductive nanoparticle core, and insulative coating surrounding the core, at least one porous external insulative shell, and a void between the insulative shell coating and the at least one external insulative shell. In an exemplary embodiment, exposure to the oscillating magnetic field can produce heat which in embodiments described herein can induce curing of the composite resin described herein. The heating produced by the exposure to the oscillating field can be induced remotely in some embodiments.

In exemplary embodiments, the composite resin can be exposed to an oscillating field that can have a frequency of about 1 Hz to about 300 GHz. The oscillating field type, frequency, and filler core type can be determined by one of ordinary skill in the art by methods known in the art. The oscillating field described herein can be an electromagnetic field, an oscillating electric field, or an oscillating magnetic field.

In some exemplary embodiments, the oscillating magnetic field described herein can have a frequency of about 30 kHz to about 1.0 MHz. The oscillating field can include, but is not limited to low frequency magnetic fields, radio waves, microwaves, and the like. The composite resin described herein can be exposed to a low frequency magnetic field having a frequency of about 1 Hz to about 100 kHz.

The radio waves described herein can be extremely low frequency radio waves (e.g., less than about 3 kHz), very low frequency radio waves (e.g., about 3 kHz to about 30 kHz), low frequency radio waves (e.g., about 30 kHZ to about 300 kHz), medium frequency radio waves (e.g., about 300 kHz to about 3 MHz), high frequency radio waves (e.g., about 3 MHz to about 30 MHz), very high frequency radio waves (e.g., about 30 MHz to about 300 MHz), ultra-high frequency radio waves (e.g., about 300 MHz to about 3 GHz), super high frequency radio waves (e.g., about 3 GHz to about 30 GHz), or extremely high frequency radio waves (e.g., about 30 GHz to about 300 GHz).

The composite resin described herein can be exposed to extremely low frequency radio waves having a frequency of less than about 3 kHz. The composite resin described herein can be exposed to very low frequency radio waves having a frequency of about 3 kHz to about 30 kHz. The composite resin described herein can be exposed to low frequency radio waves having a frequency of about 30 kHz to about 300 kHz. The composite resin described herein can be exposed to medium frequency radio waves having a frequency of about 300 kHz to about 3 MHz. The composite resin described herein can be exposed to high frequency radio waves having a frequency of about 3 MHz to about 30 MHz. The composite resin described herein can be exposed to very high frequency radio waves having a frequency of about 300 MHz to about 3 GHz. The composite resin described herein can be exposed to ultra-high frequency radio waves having a frequency of about 300 MHz to about 3 GHz. The composite resin described herein can be exposed to super high frequency radio waves having a frequency of about 3 GHz to about 30 GHz. The composite resin described herein can be exposed to extremely high frequency radio waves having a frequency of about 30 GHz to about 300 GHz.

Microwaves are short waves of electromagnetic energy that can vary in frequency from about 300 MHz to about 1000 GHz. As used herein, microwaves can refer to microwave dielectric heating and can encompass a frequency range of about 900 MHz to about 3 GHz. As used herein, microwaves can refer to frequencies of about 900 MHz to about 950 MHz, L Band microwaves (e.g., less than about 1 GHz to about 2 GHz), S Band microwaves (e.g., about 2 GHz to about 4 GHz), or C Band Microwaves (e.g., about 4 GHz to about 8 GHz).

The composite resin described herein can be exposed to microwaves having a frequency of about 900 MHz to about 1 GHz. The composite resin described herein can be exposed to L Band microwaves having a frequency of about 1 GHz to about 2 GHz. The composite resin described herein can be exposed to S Band microwaves having a frequency of about 2 GHz to about 4 GHz. The composite resin described herein can be exposed to C Band microwaves having a frequency of about 4 GHz to about 8 GHz.

In some embodiments of the method described herein, the time the composite resin is exposed to the oscillating magnetic field can be about 10 seconds to about 5 minutes. In some exemplary embodiments, the composite resin can be exposed to the oscillating magnetic field can be about 10 seconds to about 60 seconds. The time of exposure to the oscillating magnetic field described herein can be used to control the curing of the composite resin of an embodiment.

The nanoparticle core of the method described herein can be selected from an iron oxide nanoparticle, a cobalt nanoparticle, or a gold nanoparticle. The nanoparticle core described herein can have a diameter of about 5 nm to about 25 nm. In some exemplary embodiments, the inductive shell coating described herein can have a thickness of about 10 nm to about 50 nm, and the at least one porous external insulative shell described herein can have a thickness of about 5 nm to about 30 nm. In some exemplary embodiments the void can comprise about 5 nm to about 50 nm. The molding composition of the method described herein can be a capillary underfill, a molded underfill, an over-mold material, or an encapsulant.

In an embodiment of the method described herein, the void disposed between the insulative shell coating and the at least one porous external insulative shell can be produced by subjecting the conductive nanoparticle core to a size reduction process. For example, the size reduction process can be magnetic roasting. For example, in exemplary embodiments the nanoparticle core can be a hematite iron oxide nanoparticle core. This hematite iron oxide nanoparticle core can then be exposed to a low oxygen, reducing atmosphere to induce conversion to a magnetite iron oxide particle. This change, in an embodiment, can produce a void space.

In some embodiments of the method described herein, the void disposed between the insulative shell coating and the at least one porous external insulative shell can be produced by encapsulating the insulative shell coating with an external silica-organic insulative outer shell and subjecting the nanoparticle filler to hydrothermal treatment, thereby producing a void.

In embodiments, the porosity of the external insulative can be controlled based on characteristics of the silica-organic layer. In embodiments, the pores can be generated by calcination of the filler to remove the organic groups in the organic-silica layer. In embodiments, the organic-silica layer can be generated by various synthetic methods known in the art. In some embodiments, the organic-silica layer is produced by sol-gel polymerization of TEOS and C18TEMS.

The polymer resin of the method described herein can comprise a any thermosetting resin known in the art or any thermoplastic resin known in the art. In exemplary embodiments, the thermosetting resin can be an epoxy resin, a phenolic resin, a polyimide resin, an acrylate resin, a silicone resin, or combinations thereof. In further exemplary embodiments, the thermoplastic resin can be a polyethylene resin, a polypropylene resin, a polyvinyl chloride resin, a polystyrene resin, a polyethylene terephthalate resin, a polyurethane resin, an ethyl vinyl acetate resin, or combinations thereof. In some embodiments, the polymer resin is not a silicone resin. In some exemplary embodiments, the polymer resin is an epoxy resin.

Aspects of the disclosure described herein are drawn toward a molding composition produced by the methods described herein. The molding composition can be a capillary underfill, a molded underfill, an over-mold material, or an encapsulant in embodiments.

Further still, aspects of the disclosure are drawn towards a multidie assembly comprising a molding composition comprising the polymer filler composite resin described herein. In embodiments, the multidie assembly can comprise a molding composition produced by one or more of the methods described herein. For example, the molding composition can be a capillary underfill, a molded underfill, an over-mold material, or an encapsulant.

### EXAMPLES

Examples are provided herein to facilitate a more complete understanding of the invention. The following examples illustrate the exemplary modes of making and practicing the invention. However, the scope of the invention is not limited to specific embodiments disclosed in these Examples, which are for purposes of illustration only, since alternative methods can be utilized to obtain similar results.

### Example 1

### Nanorattle and Core-shell Nanoparticles for Inductive Heating of Underfills

Without wishing to be bound by theory, and described herein, is the incorporation of iron oxide magnetic particles encased in a silica shell, either in core-shell structures or nanorattles. Without wishing to be bound by theory, this will allow for the remote inductive heating of underfills thereby enabling the independent curing in multidie technology.

Over the years, the semiconductor industry has perfected thermoset formulations capable of withstanding the high thermal and mechanical demands of chips as they cycle between high and low computational loads. Thermosets offer exceptional chemical and thermal durability thanks to the permanent crosslinks that form them. They are used in a variety of applications in advanced packaging from capillary underfills (CUFs) to molded underfills (MUFs) to over-mold materials. As the name thermoset indicates, their synthesis typically requires thermal energy to elicit the formation of the robust network with desirable properties, in a process known as cure. To properly fill the fine interstices of the interconnect, the resin must be heated within narrow window of viscosity, viz. the processing well, whereby the material must be able to flow in between in the narrow gaps and avoid the formation of voids and then brought up to a higher temperature to trigger full cure of the material. This feat is further complicated by the high filler contents of the composite resins, whereby a mixture of larger and smaller silica particles contributes to the thermomechanical stability of the ensemble.

To keep improving the computing performance of consumer electronics without sacrificing their dimensions, one must pack an increasing amount of transistors into smaller and smaller footprints. The leading approach until the 2010s was the reduction of node sizes using ever more sophisticated lithographic techniques. As nodes nearing atomistic resolution are now attainable via extreme UV lithography, the industry has shifted its focus to the fabrication of multidie chips, whereby tiles are stacked vertically or juxtaposed laterally in 2D, 2.5D and 3D assemblies. These constructs have the benefit of are remarkably complex in their design and have shifted the focus from lithographic prowess using comparatively simpler packaging technology to extremely advanced packaging solutions requiring ever more sophisticated strategies. Beyond resolution aspects, the sheer cost associated with achieving lower node sizes has further incentivized the industry to explore these advanced packaging methods. With the rise of these strategies comes issues that pertain to the ability to cure systems without damaging the tiles. The cure steps are especially problematic as the layering of structures poses some serious reliability concerns on account of the repeated heating needed multidie assembly.

To that end, there is a growing need for the development of materials-based strategies that will enable remote and local heating of the resin to induce curing without having to heat up the entire assembly. To that end, without wishing to be bound by theory, and described herein is the fabrication of nanofillers with an iron oxide interior and a silica shell that prevents the detrimental leaching of iron atoms which would negatively alter the dielectric properties of the underfills. We will study two types of systems wherein the silica is grown directly on the surface of the iron oxide (core-shell nanoparticles) or where a gap exists between the magnetic core and the shell (nanorattles).

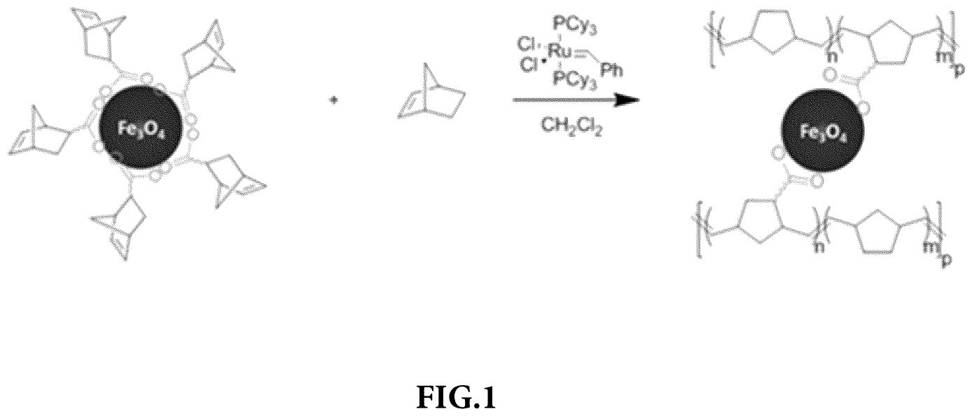

Magnetic nanoparticles have been studied in a wide range of domains ranging from magnetothermal therapy of cancer^{1,2} to hydrogenation of oleic acid.³ The attraction for these nano-heaters stems from their facile preparation and functionalization enabling the formation of a variety of complex structures with various geometries, surface chemistry and functionality. Furthermore, the ability to remotely heat with somewhat benign radio frequencies offers multiple advantages in terms of simple set up to achieve temperatures in excess of 200° C. The Simon group has developed strategies to incorporate norbornene-decorated magnetic nanoparticles as crosslinkers into shape-memory polynorbornene composites (FIG. 1).⁴ The superparamagnetic iron oxide nanoparticles (SPIONs) which play a dual role of network points and inductive heating elements, are prepared in a one-step reaction using conventional oxidation of iron (III) acetylacetonate (Fe(Acac)₃) in the presence of 5-norbornene-2-carboxylic acid. The composites with 0.1 and 20 wt. % of Fe₃O₄ nanoparticles were obtained via ring-opening metathesis copolymerization.

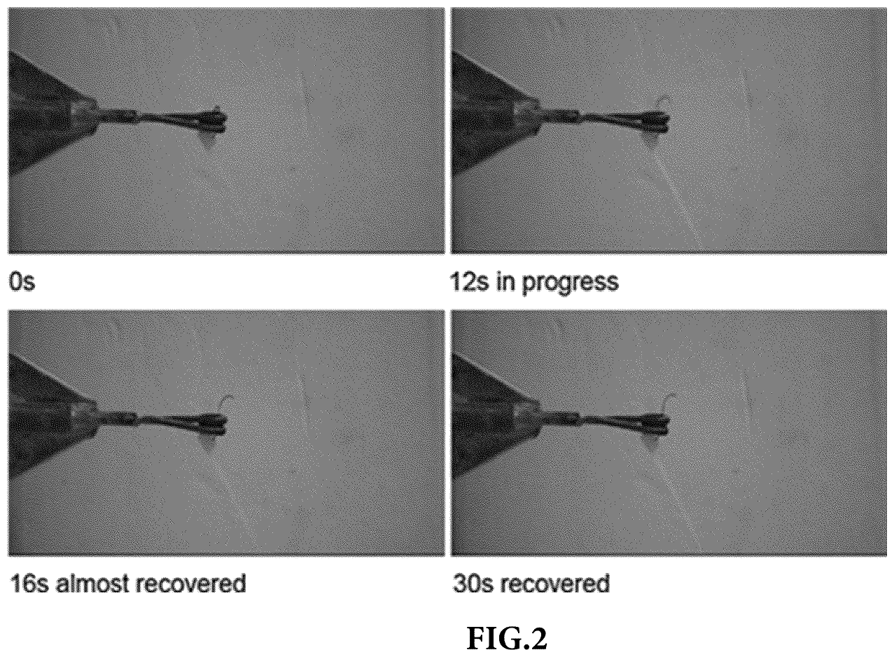

Simon and coworkers further demonstrated the importance of surface functionalization on SPIONs on the shape-memory behavior of polyurethane (PU) composites based on Desmopan DP 2795A SMP (FIG. 2).⁵ Two series of PU/Fe₃O₄ nanocomposite films based on the shape-memory PU and single layer or bilayer OA-coated Fe₃O₄ NPs were prepared by solvent casting. The presence of free OA enhanced the elasticity of the nanocomposite films. Nanocomposite films with bilayer OA-coated Fe₃O₄ NPs exhibited superior shape-memory properties compared to those with single-layer OA-coated Fe₃O₄ NPs. The recovery time of the nanocomposite films in a magnetic field decreased as the NPs content increased.

Described herein, and without wishing to be bound by theory, we can fabricate molding compounds with two types of nanofillers with an outside silica layer and an iron oxide core. We will be using the nomenclature FeₓO_{y}@SiO₂ to refer to simple core-shell structures and FeₓO_{y}@void@SiO₂ to identify the nanorattles. ^{6, 7} For the sake of simplicity, we will focus on silica shells since silica nanoparticles are common fillers in microelectronics. Also, while it is possible to change the number of magnetic cores per nanoparticle, the shape of the particles (e.g. ellipsoid or raspberry), as well as the surface properties (roughness and chemical functionality), insofar as possible, we will focus here exclusively on spherical systems that contain one magnetic element per nanoparticle with silanol surfaces.

Without wishing to be bound by theory, the following non-limiting considerations can guide our approach: We can determine a shell thickness that will provide heat transfer to the curable resin while maintaining mechanical properties and precluding atomic metal migration into the cured matrix. The porosity of the silica shell can have an impact on the heat transfer properties of the nanorattles. Likewise, the greater the void between the magnetic core and the shell, the less efficient the heat transfer will be to the surrounding curing matrix. The remnant magnetism can be detrimental to the performance of the chip. In some embodiments, we will focus on superparamagnetic cores. We can determine the loading of magnetic nanoobjects that will trigger the cure without overcure. Conversely, the magnetic dosage can be tuned to allow enough flowability of the molding compound, i.e. to be in the rheological processing window, while ensuring a speedy and complete cure.

A function of liquid encapsulant materials, including underfill, is to enhance the reliability of packages by physically protecting and bonding various components like silicon, interconnect metals, and composite substrates. Additionally, they help dissipate and redistribute stresses and strains caused by thermal expansion mismatches between different packaging materials and other factors such as handling. Stacking die and stitching them together enables high bandwidth communication at low latency and enable to grow the package pas the litho-reticular lens limitation but reliability is a key concern as everything continues to shrink. Narrow first layer interconnects (FLIs) enable shorter interconnection length and thus better electrical performance. With reduced form factor of the FLI, there is increased pressure to both flowability and ability to cure and initiate the reaction in the “interstices.”

Our approach which can be based on inductive heating or dielectric heating can revolutionize the approach to multidie technology in that it (i) is a sustainable and energy-efficient heating method and (ii) will avoid the need to repeatedly put assemblies inside a furnace thereby risking damage to previously assembled layers. The starting materials are conveniently cheap and readily available, and the strategies that we propose are scalable.

Non-Limiting, Exemplary Fabrication of FeₓO_{y}@SiO₂

Leveraging our experience in the synthesis of functional SPIONs, in embodiments we will prepare OA-coated magnetite NPs (from 5 to 25 nm) using the thermal decomposition method, followed by ligand exchange by suspending them in CHCl₃ and adding an aqueous solution containing hexadecyltrimethylammonium bromide, aka cetyltrimethylammonium bromide (CTAB, 97%), followed by a prolonged sonication (1 h) and thermal treatment (70° C., 10 min). This step can allow for the enhanced transfer of the SPIONs between oil and aqueous phase. Once the CTAB-coated particles are obtained, we can form the silica outer shell by leveraging a modified inverse microemulsion. Briefly, the SPIONs can serve as nucleation seeds for the silica precursors (viz. tetraethyl orthosilicate, TEOS). Using cyclohexane as the oil phase, urea or ammonia as a basic catalyst, butanol or Igepal® CO-520 as a co-surfactant, TEOS will be added to form a stable microemulsion which will be transferred into a Teflon®-lined autoclave at 120° C. followed by centrifugation (400 rpm/15 min) and repeated washes with ethanol and distilled water. Finally, we will dry the sample in an oven with sequential heating cycle from 60 to 550° C. to form the outer mesoporous silica shell.

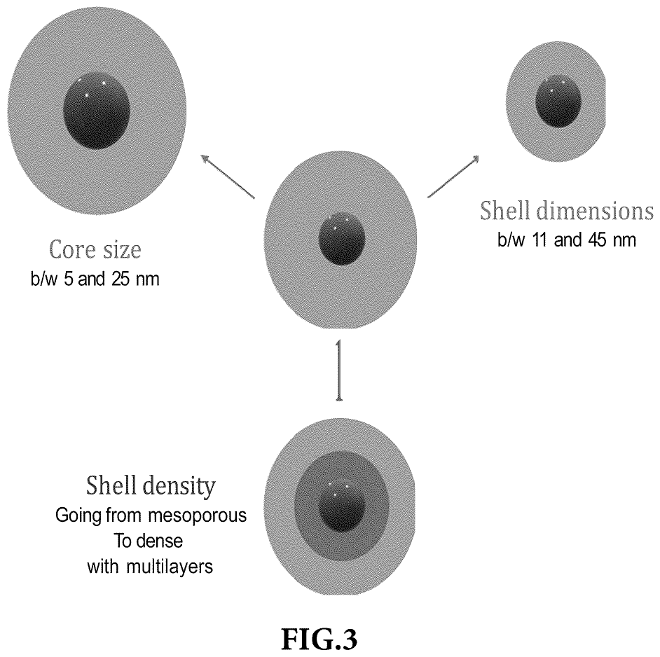

Under embodiments, uniform silica shells can be varied from about 11 to 45 nm⁸ (FIG. 3). The conditions for coating can be adapted to the size of the magnetic core with aqueous domain being commensurate with the shell thickness. Likewise, we will adjust the conditions to alter the shell porosity. One concern for too high porosity is the possibility of metal or metal oxide to migrate from the core to the molding compound. Denser silica will be readily achieved by using the Stöber method using ethanol and an ammonia solution with mechanical agitation.⁹ Interestingly, the density of the silica can be even varied throughout the shell for example, see the creation of Fe₃O₄@nSiO₂@mSiO₂ microspheres.¹⁰ In embodiments, we can introduce epoxy rings on silsesquioxane moieties. Consequently, in embodiments, we will be varying the shell thicknesses and porosities to investigate their impact on the molding processing as well as the ultimate properties of the material e.g. Tg, coefficient of thermal expansion (CTE).

Non-limiting, Exemplary Fabrication of FeₓO_{y}@void@SiO₂

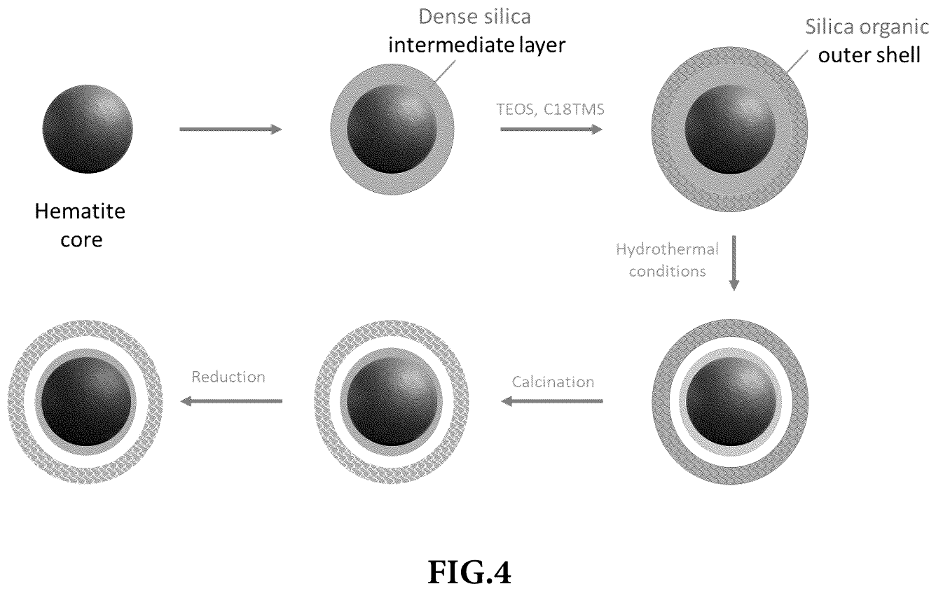

Similarly, in embodiments we can investigate the influence of the void in nanorattles on the overall performance of the materials. Without wishing to be bound by theory, we can use the hydrothermal route followed by hydrogen reduction. We opted for this route over templated approaches because of the difficulty to create silica-coatings via templating approaches and the overall atom-inefficiency of the process. For example, in Zhao et al. ,11 this approach relies on the formation of a dense coating of silica around the hematite (Fe₂O₃) magnetic nanoparticle core, followed by the formation of the silica-organic outer shell using a TEOS and n-octadecyltrimethoxysilane (C18TMS). This porous outer layer can allow for the formation of a gap layer with the outer shell and the dense silica coating via hydrothermal treatment. Upon subsequent calcination and hydrogenation, the hematite is converted to magnetite to form the desired structures (FIG. 4). In embodiments, we can focus on getting larger and continuous quantities of SPIONs by leveraging the latest findings in the field of synthesis in flow of nanoparticles.¹² Indeed, continuous flow will allow to synthesize particles of smaller diameter and enhanced stability compared to segmented flow or batch synthesis. By varying the shells of pure TEOS and TEOS/C18TMS and controlling the hydrothermal conditions, we will be able to control the void dimensions.

Non-limiting, Exemplary Preparation of Uniform α-Fe₂O₃-SiO₂ Particles (H-S)

First, uniform hematite α-Fe₂O₃ particles were obtained by aging a solution that contained 2.0×10⁻² M FeCl₃ and 1×10⁻³ M HCl at 373K for 24 h. Afterwards, hematite particles (50 mg) were well dispersed in a solution that contained isopropyl alcohol (200 mL), deionized water (40 mL), and aqueous ammonia (6 mL). TEOS (0.15 mL) was then added, and the mixture was continuously stirred at room temperature for 8 h. The resultant particles were separated by centrifugation and redispersed in 5 mL of ethanol for use (Suspension I).

### Non-limiting, Exemplary Preparation of Hollow Magnetic Mesoporous Silica Spheres (HMMS)

In a typical synthesis procedure, Suspension I was well dispersed in a solution composed of H₂O (2 mL), EtOH (10 mL), and NH₃ (0.72 mL) with a final molar ratio of 1:2.29:0.34. Afterwards, a 0.3 mL mixture of TEOS/C18TMS with a molar ratio of 4.7:1 was added dropwise to the reaction mixture under vigorous stirring and subsequently stirred at ambient temperature for 6 h. The resultant C18TMS-incorporated core-shell particles was separated by centrifugation and re-dispersed in a series of hydrothermal solutions composed of water and ethanol with different H₂O volume proportions (H₂O vol. %: 0, 25, 50, 75, 100), respectively. In terms of the hydrophobic surfaces of the as-synthesized HMMS before calcination, a certain proportion of ethanol as dispersant support was added to the hydrothermal solution. The suspensions were then sealed in Teflonlined autoclaves and heated at 403K for 15 h. The solid products after hydrothermal treatment were recovered by centrifugation and dried at room temperature overnight. The as-synthesized materials were then calcined in air at 823K for 6 h. The final HMMSs were obtained by reduction in H₂ (4 vol %)/N₂ gas at 673K for 3 h.

### Non-Limiting, Exemplary Preparation of MCMSs

In embodiments, the synthesis procedure can be similar to method reported in W. Zhao, J. Gu, L. Zhang, H. Chen, J. Shi, J. Am. Chem. Soc. 2005,127, 8916. In embodiments, Suspension I was well dispersed in a solution composed of H₂O (2 mL), EtOH (10 mL), and NH₃ (0.72 mL) with a final molar ratio of 1:2.29:0.34. Afterwards, a 0.3 mL mixture of TEOS/C18TMS with a molar ratio of 4.7:1 was added dropwise to the reaction mixture under vigorous stirring and subsequently stirred at ambient temperature for 6 h. The resultant products were centrifuged and dried at room temperature. The as synthesized materials were then calcined in air at 823K for 6 h and then reduced in H₂ (4 vol %)/N₂ gas at 673K for 3 h. Preparation of α-Fe₂O₃-Mesoporous SiO₂ Particles (H-M): Hematite particles (80 mg) were well dispersed in a solution that contained isopropyl alcohol (200 mL), deionized water (40 mL), and aqueous ammonia (6 mL). A 0.3 mL mixture of TEOS/C18TMS with a molar ratio of 4.7:1 was added dropwise to the reaction mixture under vigorous stirring and subsequently stirred at ambient temperature for 8 h. The resultant particles were separated by centrifugation, dried, and finally calcined at 823K for 6 h.

### Evaluation of the Inductive Heating Capabilities and Rheological Properties of Molding Compounds

In embodiments, we can start by evaluating a pure epoxy resin with bisphenol-F diglycidyl ethers using either, for example, anhydride (e.g. 4-methylhexahydrophthalic anhydride, 4-methyltetrahydrophthalic anhydride) using imidazole-based catalysts (e.g. 2-ethyl-4-methylimidazole) or aromatic diamines (e.g. 2,4-diethyl-6-methylbenzene-1,3-diamine) as hardeners. In non-limiting, exemplary embodiments, and for the sake of simplicity, we can forego the utilization of tougheners (e.g. silicones, butadienes, carboxy-terminated butadiene, acrylonitrile copolymers). For each of the compositions, we can evaluate the changes in viscosity as a function of particle loading. We can evaluate the rheological properties of the particle-filled resins during the cure process as a function of temperature to determine the optimal viscosity profile for each of the compositions (from 0 to about 25 wt. %).

We can then expose the particle-filled resins to an oscillating magnetic field at different strength and varying the frequency. Practically, the sample can be placed over a 10×10 cm square bronze coil connected to a high-frequency (30-80 kHz) induction device.¹³⁻¹⁸ The temperature increase will be monitored using a thermal infrared camera to probe the maximum temperature reached for each sample. In order to reproduce the heating process as accurately as possible, we can choose a plasma-treated silicon wafer to evaluate the ability to heat up at different film thicknesses. To achieve these thicknesses, we can spin coat the resin onto the wafer at various speed. Without wishing to be bound by theory, the inherent ability to cure the resin “from within” rather than relying on heat transport in the epoxy resin can be advantageous in terms of speed of curing. Using the infrared camera, we can probe the heating efficiency of the SPIONs as a function of their characteristic core-shell-(void) dimensions and porosity.

We will look at the influence of the SPIONs on the thermal expansion coefficient and explore whether the presence of metallic core is indeed thwarted by the silica shell and (or the void). We can evaluate the thermomechanical properties of the fillers, especially looking at the heat conductivity of the composites. We can look at gel fraction to ensure full cure of the material as well as look at differential scanning calorimetry to look at the optimal cure time. Without wishing to be bound by theory, the addition of higher loadings of non-magnetic silica fillers can contribute to lengthening these times and can evaluate this on spin-coated highly filled (and therefore more representative) resins. We can look at the effect of applying additional oscillating magnetic fields to the cured composites to evaluate the temperatures that will be reached. For example, we are interested in seeing whether for a given frequency and SPION loading how whether there is a difference in temperature profile between the uncured with “freely moving” particles and the cured system. This knowledge can be important when considering the need to superimpose multiple dies for increased chip performance.

### Non-Limiting, Exemplary Experimental Plan

In embodiments, we can simultaneously synthesize and characterize the core-shell nanoparticles. Our prior experience with SPIONs can help us quickly produce the needed particles. We can evaluate the synthesis of the core-void-shell nanorattles and simultaneously investigate the rheological properties of the first batch of filled composite resins. We can study the cure kinetics, and thermomechanical properties of the resins described herein. The rheology and thermomechanical characterization can assist in the selection process. We can perform gel fraction and DSC tests to evaluate the degree of conversion for different exposure times and frequency. Additionally, we will study the presence and impact of the magnetic nanoparticles on heat transfer.

### References Cited Herein

1. E. A. Kwizera, S. Stewart, M. M. Mahmud and X. He, Journal of Heat Transfer, 2022, 144.
2. J.-H. Lee, B. Kim, Y. Kim and S.-K. Kim, Scientific Reports, 2021, 11, 4969.
3. C. L. Roman, N. da Silva Moura, S. Wicker, K. M. Dooley and J. A. Dorman, ACS Applied Nano Materials, 2022, 5, 3676-3685.
4. S. Bai, H. Zou, H. Dietsch, Y. C. Simon and C. Weder, Macromol. Chem. Phys., 2014, 215, 398-404.
5. H. Zou, C. Weder and Y. C. Simon, Macromolecular Materials and Engineering, 2015, 300, 885-892.
6. S.-L. Abram, P. Yep and K. M. Fromm, CHIMIA, 2019, 73, 12.
7. M. Priebe and K. M. Fromm, Chemistry-A European Journal, 2015, 21, 3854-3874.
8. J. Kim, H. S. Kim, N. Lee, T. Kim, H. Kim, T. Yu, I. C. Song, W. K. Moon and T. Hyeon, Angewandte Chemie International Edition, 2008, 47, 8438-8441.
9. M. Yang, W. Yang, L. Chen, M. Ding, C. Li and D. Shi, Dose-Response, 2020, 18, 1559325820906662.
10. Y. Deng, D. Qi, C. Deng, X. Zhang and D. Zhao, J. Am. Chem. Soc., 2008, 130, 28-29.
11. W. Zhao, H. Chen, Y. Li, L. Li, M. Lang and J. Shi, Adv Funct Mater, 2008, 18, 2780-2788.
12. J. Schemberg, A. E. Abbassi, A. Lindenbauer, L.-Y. Chen, A. Grodrian, X. Nakos, G. Apte, N. Khan, A. Kraupner, T.-H. Nguyen and G. Gastrock, ACS Applied Materials & Interfaces, 2022, 14, 48011-48028.
13. D. Abliz, Y. Duan, L. Steuernagel, L. Xie, D. Li and G. Ziegmann, Polymers and Polymer Composites, 2013, 21, 341-348.
14. C. J. Yungwirth, E. D. Wetzel and J. M. Sands, 2003.
15. C. Severijns, S. T. de Freitas and J. A. Poulis, International Journal of Adhesion and Adhesives, 2017, 75, 155-164.
16. Y. Li, X. Hu, L. Hao, J. Liang, D. Wu, A. Sun, Z. Xi, P. Jin and Y. Xiong, An induction curing technique for CFRP laminate via magnetic particle-induced in situ heating, Polymer Composites, vol. 46, issue 7 (2024) pp. 6169-78.
17. Y. Zhang, C. Wu, W. Zhang, X. Zeng and X. Han, Polym Composite, 2024, 45, 569-580.
18. Y. Li, A. Sun, X. Hu, D. Wu, L. Hao, Y. Yan and Z. Xi, J Mater Sci, 2024, 59, 6765-6777.

Additional References cited herein: Zhang et al. (US Patent No. 11,879,073), Polus (US Application No. 2014/0299268), Williams (US Patent No. 12,502,885), Cavaleriro et al., US Application No. 2007/01976678.

### EQUIVALENTS

Those skilled in the art will recognize, or be able to ascertain, using no more than routine experimentation, numerous equivalents to the specific substances and procedures described herein. Such equivalents are considered to be within the scope of this invention and are covered by the following claims.

What is claimed:

1. A composite resin composition comprising a polymer resin and a nanoparticle filler, wherein the nanoparticle filler comprises:
a nanoparticle core, wherein the core comprises a material that is remotely heatable by exposure to an oscillating field;
an insulative coating surrounding the core;
at least one porous external insulative shell; and
a void disposed between the insulative coating and the at least one porous external insulative shell.

2. The composition of claim 1, wherein
the material is selected from the group consisting of a metal, a metal oxide, a metal alloy, a carbonaceous material, a metal nitride, a metal carbide, or a composite material thereof;
the insulative coating comprises silica;
the at least one porous external insulative shell comprises a material selected from the group consisting of a glassy polymer, mesoporous silica, nanoporous silica, or a combination thereof; and
the nanoparticle filler does not comprise a ceramic.

3. The composition of claim 1, wherein
the nanoparticle core has a diameter of about 5 nm to about 25 nm;
the insulative shell coating has a thickness of about 10 nm to about 50 nm;
the at least one porous external insulative shell has a thickness of about 5 nm to about 30 nm; and
the void comprises about 5 nm to about 50 nm.

4. The composition of claim 1, wherein the nanoparticle core is selected from an iron oxide nanoparticle, a cobalt nanoparticle, a gold nanoparticle, a titanium dioxide nanoparticle, a silicon dioxide nanoparticle, a zinc oxide nanoparticle, or an aluminum oxide nanoparticle.

5. The composition of claim 4, wherein the iron oxide nanoparticle is a magnetite iron oxide nanoparticle.

6. The composition of claim 1, wherein the composition comprises about 0.1 wt. % to about 20 wt. % of the nanoparticle filler.

7. The composition of claim 1, wherein the composition is a capillary underfill, a molded underfill, an over-mold material, or an encapsulant.

8. The composition of claim 1, wherein the polymer resin is selected from a thermosetting resin or a thermoplastic resin,
wherein the thermosetting resin selected from the group consisting of an epoxy resin, a phenol resin, a polyimide, an acrylate resin, a silicone resin, or a combination thereof; and
wherein thermoplastic resin selected from the group consisting of a polyethylene, a polypropylene, a polyvinyl chloride, a polystyrene, a polyethylene terephthalate, a polyurethane, an ethyl vinyl acetate, or a combination thereof.

9. A method of producing a molding composition, the method comprising:
loading a nanoparticle filler into a polymer resin, thereby producing a composite resin, wherein the nanoparticle filler comprises:
a nanoparticle core, wherein the core comprises a material that is remotely heatable by exposure to an oscillating field;
an insulative coating surrounding the core,
at least one porous external insulative shell, and
a void between the insulative shell coating and the at least one porous external insulative shell,
depositing the composite resin onto a substrate or into a mold; and
exposing the composite resin to an oscillating field, thereby curing the composite resin and forming a molding composition.

10. The method of claim 9, wherein the oscillating field is an oscillating magnetic field.

11. The method of claim 10, wherein the oscillating magnetic field has a frequency of about 20 kHz to about 1.0 MHz.

12. The method of claim 9, wherein the composite resin is exposed to the oscillating field for about 10 seconds to about 5 minutes.

13. The method of claim 9, wherein
the nanoparticle core comprises a material selected from the group consisting of a metal, a metal oxide, a metal alloy, carbon material, a metal nitride, a metal carbide, or a combination thereof;
the insulative shell coating comprises silica; and
the at least one porous external insulative shell comprises a material selected from the group consisting of a glassy polymer, mesoporous silica, nanoporous silica, or a combination thereof; and
the nanoparticle filler does not comprise a ceramic.

14. The method of claim 9, wherein
nanoparticle filler is loaded at about 0.1 wt. % to about 20 wt. % of the composite resin;
the nanoparticle core has a diameter of about 5 nm to about 25 nm;
the insulative shell coating has a thickness of about 10 nm to about 50 nm;
the at least one porous external insulative shell has a thickness of about 5 nm to about 30 nm; and
the void comprises about 5 nm to about 50 nm.

15. The method of claim 9, wherein the core is selected from an iron oxide nanoparticle, a cobalt nanoparticle, or a gold particle.

16. The method of claim 9, wherein the void disposed between the insulative shell coating and the at least one porous external insulative shell is produced by:
subjecting the nanoparticle core to magnetization roasting or coating the nanoparticle core with an insulative coating;
encapsulating the insulative shell coating with an external silica-organic insulative outer shell; and
subjecting the nanoparticle filler to hydrothermal treatment, thereby producing a void.

17. The method of claim 9, wherein the molding composition is a capillary underfill, a molded underfill, an over-mold material, or an encapsulant.

18. The method of claim 9, wherein the polymer resin is selected from a thermosetting resin or a thermoplastic resin,
wherein the thermosetting resin selected from the group consisting of an epoxy resin, a phenol resin, a polyimide, an acrylate resin, a silicone resin, or a combination thereof; and
wherein thermoplastic resin selected from the group consisting of a polyethylene, a polypropylene, a polyvinyl chloride, a polystyrene, a polyethylene terephthalate, a polyurethane, an ethyl vinyl acetate, or a combination thereof.

19. A multidie assembly comprising a molding composition produced by the method of claim 9.

20. The assembly of claim 19, wherein the molding composition is a capillary underfill, a molded underfill, an over-mold material, or an encapsulant.
